(19) United States
(12) Patent Application Publication
(10) Pub. No.: US 2026/0107593 A1
(43) Pub. Date: Apr. 16, 2026

(54) IMAGE SENSING DEVICE

(71) Applicant: SK hynix Inc., Icheon-si (KR)

(72) Inventors: Won Jin KIM, Icheon-si (KR); Young Woong DO, Icheon-si (KR)

(21) Appl. No.: 19/056,382

(22) Filed: Feb. 18, 2025

(30) Foreign Application Priority Data
Oct. 15, 2024 (KR) 10-2024-0140289

(51) Int. Cl. H10F 39/00

(52) U.S. Cl. CPC H10F 39/8053; H10F 39/805; H10F 39/807; H10F 39/024

(57) ABSTRACT

An image sensing device may include a photoelectric conversion structure and a light incident structure disposed over the photoelectric conversion structure. The light incident structure includes a grid pattern, a plurality of color filters and a light concentration layer with a flat upper surface. The light concentration layer includes an adjusting portion formed on at least a portion of the light concentration layer to adjust a focusing position of an incident light.

### CROSS-REFERENCES TO RELATED APPLICATION

This patent document claims priority under 35 U.S.C. § 119(a) to Korean application number 10-2024-0140289, filed on Oct. 15, 2024, in the Korean Intellectual Property Office, which is incorporated herein by reference in its entirety.

### TECHNICAL BACKGROUND

Example embodiments of the disclosed technology relate to an image sensing device, and more particularly to an image sensing device including pixels.

### BACKGROUND

An image sensing device may include an optical element configured to convert an optical image into an electrical signal. The optical element may include, for example, a complementary metal oxide semiconductor image sensor (CMOS image sensor). The CMOS image sensor may be integrated on each of spaces, which may be called as pixels, on a semiconductor substrate.

As there is an increasing demand for miniaturization and high resolution in current image sensing devices, a reduction in pixel size is required. However, the reduction in pixel size may lead to a decrease in quantum efficiency (QE) as well as a reduction in focal length, potentially resulting in a deterioration of image quality.

### SUMMARY

In one aspect, there may be provided an image sensing device. The image sensing device may include a photoelectric conversion structure and a light incident structure. The photoelectric conversion structure may include a pixel isolation layer configured to define a plurality of pixels, each pixel including a photoelectric conversion element configured to generate electronic signals in response to a reception of light incident on the each pixel. The light incident structure may be disposed on the photoelectric conversion structure and configured to focus an incident light onto the photoelectric conversion element.

In example embodiments, the light incident structure may include a grid pattern, a plurality of color filters and a light concentration layer stacked sequentially towards an incident surface. The grid pattern may be configured to overlap the pixel isolation layer. The grid pattern may have a first refractive index. Each of the plurality of color filters may be disposed on the grid pattern and in a region surrounded by the grid pattern. Each of the plurality of color filters may have a second refractive index greater than the first refractive index. The light concentration layer may be disposed on the plurality of color filters. The light concentration layer may have a flat incident surface to receive the incident light. The light concentration layer may include an adjusting portion disposed on at least a portion of the light concentration layer and disposed to overlap with the pixel isolation layer and configured to adjust a focusing position of the incident light.

In another aspect, there may be provided an image sensing device. The image sensing device may include a first substrate, a plurality of photoelectric conversion elements, a pixel isolation layer, an anti-reflective layer, an grid pattern, a plurality of color filters and a passivation layer.

In example embodiments, the first substrate may have a front side and a back side opposite to the front side. The plurality of photoelectric conversion elements may be formed in matrix form in the first substrate. The pixel isolation layer may be formed in the first substrate and configured to optically separate the plurality of photoelectric conversion elements from each other. The anti-reflective layer may be formed on the back side of the first substrate. The grid pattern may include a first refractive index and be positioned on the anti-reflective layer to overlap the pixel isolation layer. The plurality of color filters may be formed on the grid pattern and include a second refractive index higher than the first refractive index. The passivation layer may comprise an adjusting portion disposed at least one portion of the passivation layer that corresponds to the pixel isolation layer, the adjusting portion having a second thickness smaller than the first thickness.

According to example embodiments, by stacking layers with different refractive indices, the focusing position of the incident light of a small pixel may be adjusted by changing a path of the incident light. Since the layers with the different refractive indices may act as lenses by themselves, it may not be necessary to provide a separate high-curvature micro lens, and the incident light may be focused to a desired position, thereby improving QE characteristics of the image sensing device.

Further, the image sensing device of example embodiments may utilize the flat light concentration layer to reduce damages of the micro lens during shipment and to protect the image sensing device from external factors as the light concentration layer may also act as the passivation layer.

Furthermore, even if the flat light concentration layer may be formed on the image sensing device, the trench-shaped adjusting portion may be formed to guide the position of the pixels, which may prevent errors during factory inspection of the image sensing device.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is a block diagram illustrating an image sensing device in accordance with example embodiments.

FIG. 2 is a perspective view illustrating an image sensing device in accordance with example embodiments.

FIG. 3 is a cross-sectional view illustrating a unit pixel, enlarged in on a portion “A” of FIG. 2.

FIG. 4 is a plan view illustrating a light concentration layer in accordance with example embodiments.

FIG. 5 is a plan view illustrating a light concentration layer in accordance with example embodiments.

FIG. 6A is a cross-sectional view taken along a line A-A′ of FIG. 5.

FIG. 6B is a cross-sectional view taken along a line B-B′ in FIG. 5.

FIG. 7 is a graph showing quantum efficiency (QE) of an image sensing device in accordance with example embodiments.

FIG. 8 is a flow chart illustrating a method of manufacturing an image sensing device in accordance with example embodiments.

FIGS. 9A to 9E are cross-sectional views of each step illustrating a method of manufacturing an image sensing device in accordance with example embodiments.

### DETAILED DESCRIPTION

The advantages and features of the disclosed technology, and methods of achieving them, will be described with various embodiments with reference to the accompanying drawings. The disclosed technology is not limited to the embodiments disclosed herein, but will be embodied in many different forms. The dimensions and relative sizes of the layers and regions in the drawings may be exaggerated for clarity of description. Throughout the specification, like reference numerals refer to like components.

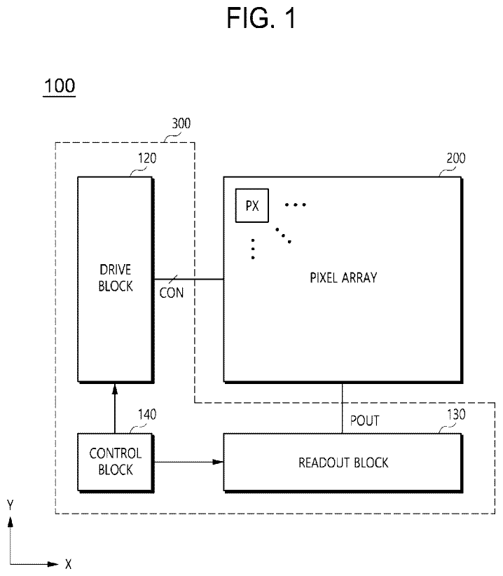

FIG. 1 is a block diagram illustrating an image sensing device in accordance with example embodiments.

Referring to FIG. 1, an image sensing device 100 may be or include a complementary metal oxide semiconductor image sensor (CIS) configured to convert a light into an electrical signal. In example embodiments, the light may include photons that may produce a photoelectric effect. In some implementations, the light may also refer to an electromagnetic radiation or an electromagnetic wave corresponding to specific wavelength bands in an electromagnetic spectrum, including a radio wave, a microwave, an infrared ray, a near-infrared ray, a visible light, an ultraviolet light, an X-ray, or a gamma ray.

The image sensing device 100 may include a pixel array 200 and a logic assembly 300.

The pixel array 200 may include a plurality of pixels PX. For example, the plurality of pixels PX may be arranged in a matrix including columns and rows.

The logic assembly 300 may include a drive block 120, a readout block 130 and a control block 140.

In example embodiments, the pixel array 200 may include a plurality of rows and a plurality of columns. The plurality of pixels PX in a row (for example, x direction) of one of the plurality of rows may each receive a same pixel control signal from the drive block 120. The plurality of pixels PX in a column (for example, y direction) of one of the plurality of columns may be connected to a single column line to output pixel signals to the readout block 130.

The drive block 120 may drive the pixels PX of the pixel array 200 in response to a timing signal outputted from the control block 140. For example, the drive block 120 may output at least one control signal CON for selecting and controlling the pixels PX in at least one row line of the plurality of row lines of the pixel array 200.

The readout block 130 may detect a pixel signal Pout outputted from the pixel array 200 in accordance with a control of the control block 140. The readout block 130 may generate image data from the detected pixel signal Pout. The image data may be pixel data in a digital form, which may be an analog-to-digital conversion of pixel signals in an analog form. To generate the pixel data in the digital form, the readout block 130 may include a dual correlation sampler (not shown) and an analog-to-digital converter (not shown). In some implementations, the readout block 130 may further include a buffer circuit (not shown) configured to temporarily store the pixel data outputted from the analog-to-digital converter and output the pixel data to the outside in accordance with the control of the control block 140.

The control block 140 may generate a timing signal for controlling operations of the drive block 120 and the readout block 130.

In example embodiments, the image sensing device 100 may further include an image signal processor (not shown). Based on a request of the image signal processor, the control block 140 may generate timing signals at appropriate timings. For example, the control block 140 may include a logic control circuit, a phase lock loop (PLL) circuit, a timing control circuit, a communication interface circuit, etc.

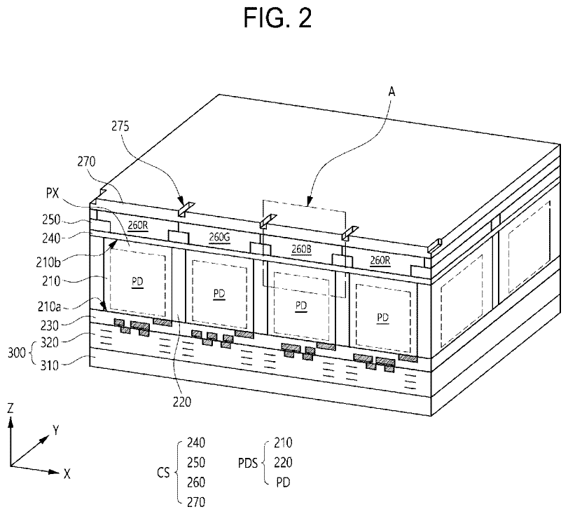

FIG. 2 is a perspective view illustrating an image sensing device in accordance with example embodiments.

Referring to FIG. 2, the image sensing device 100 may include a pixel array 200 stacked on a logic assembly 300.

For example, the pixel array 200 may include a photoelectric conversion structure PDS and a light incident structure CS.

For example, the photoelectric conversion structure PDS may include a first substrate 210, a pixel isolation layer 220 and a plurality of photoelectric conversion elements PD.

For example, the first substrate 210 may be or include bulk silicon or silicon-on-insulator (SOI). In some implementations, the first substrate 210 may include at least one of germanium silicide, indium antimonide, lead telluride compound, indium arsenide, indium phosphide, gallium arsenide, or gallium antimonide. The first substrate 210 may also include an epitaxial growth layer. The first substrate 210 may be or include an epitaxial layer formed on a base substrate. The substrate 210 may include, for example, first or second conductive impurities. For example, the first conductive type may be a p-type, and the second conductive type may be an n-type opposite to the first conductive type. The first substrate 210 may include a first surface 210a corresponding to a front side, and a second surface 210b corresponding to a back side.

The pixel isolation layer 220 may be formed to make contact with at least one of the first surface 210a or the second surface 210b of the first substrate 210. The pixel isolation layer 220 may form a space in the first substrate 210 in which the photoelectric conversion element may be to be formed. The pixel isolation layer 220 may be configured as a deep trench type or a junction type. For example, the pixel isolation layer 220 may be formed in a mesh structure in which portions of the pixel isolation layer 220 are connected as one region between adjacent pixels, thereby defining regions where the plurality of pixels arranged in a matrix form may be formed.

Each of the plurality of photoelectric conversion devices PD may be formed in the first substrate 210. For example, the photoelectric conversion device PD may generate photoelectric charges in response to an incident light. In example embodiments, the photoelectric conversion device PD may include a photo diode, a photo transistor, a photo gate, a pinned photo diode (PPD), or a combination thereof.

The pixel array 200 may further include a circuit layer 230. The circuit layer 230 may include a plurality of pixel transistors, a plurality of floating diffusions and wiring layers electrically connected between the pixel transistors and the floating diffusions, which may be configured to convert the photoelectric charges detected by the at least one photoelectric conversion element PD into a pixel signal. The circuit layer 230 may be formed over the first surface 210a of the first substrate 210. For example, the plurality of pixel transistors may include a transfer transistor, a reset transistor, a drive transistor and a selection transistor. A configuration and an arrangement of the pixel transistors and the floating diffusion may vary, an example of which is disclosed in U.S. Publication No. 2023/0032117, the disclosure of which is hereby incorporated by reference.

The light incident structure CS may transmit and focus the incident light to the photoelectric conversion element PD. The light incident structure CS may be formed over the second surface 210b of the first substrate 210. In the example as shown in FIG. 2, the circuit layer 230 and the light incident structure CS may be disposed on different sides of the first substrate 210.

In example embodiments, the light incident structure CS may include an anti-reflective layer 240, a grid pattern 250, a plurality of color filters 260 and a light concentration layer 270.

For example, the anti-reflective layer240 may include at least one of silicon oxide, silicon nitride, silicon oxynitride, aluminum oxide, hafnium oxide, or combinations thereof. Although not shown, at least one insulating interlayer may be further interposed between the anti-reflective layer 240 and the photoelectric conversion structure PDS.

For example, the grid pattern 250 may be positioned to overlap with the pixel isolation layer 220. The grid pattern 250 may also define the regions where the plurality of pixels PX formed. The grid pattern 250 may include an air with a refractive index of 1. In some implementations, the grid pattern 250 may include a hybrid air type structure that may include a conductive layer under an air layer.

Each of the color filters 260 may be configured to transmit a specific wavelength of light to the photoelectric conversion element (PD) of a corresponding pixel (PX). The color filters 260 may comprise a plurality of different color filters. For example, the color filters 260 may include a combination of a green color filter, a blue color filter, and a red color filter. In some implementations, the color filters 260 may be arranged in a Bayer pattern, or may alternatively be configured to include other color filters, such as cyan, magenta, white or yellow.

The light concentration layer 270 may be formed over the color filters 260. The light concentration layer 270 may include a material substantially the same as a material of a micro lens. The light concentration layer 270 may include a flat upper surface with a curvature close to zero. Accordingly, the light concentration layer 270 may have a uniform and thin thickness compared to a convex-shaped micro lens. For example, a lower surface of the light concentration layer 270 may be in direct contact with the color filters 260. When the light concentration layer 270 may be formed of or include the material of micro lens, a refractive index of the light concentration layer 270 and the color filters 260 may be greater than the refractive index of the grid pattern 250.

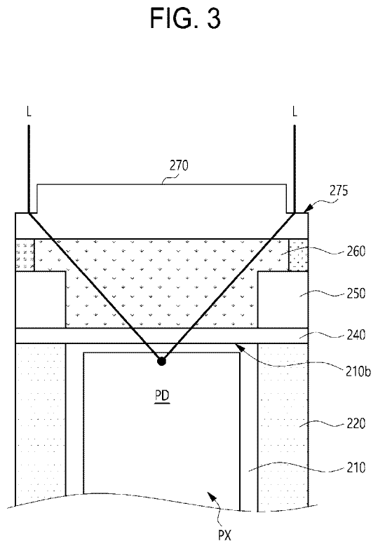

The light concentration layer 270 may further include an adjusting portion 275 configured to change a focal position based on a size of the pixel. As further described with reference to FIG. 3, for example, an incidence path of the light may be varied by the adjusting portion 275. In the example, the adjusting portion 275 may guide the incident light to focus onto the photoelectric conversion element PD formed within a small pixel region.

The logic assembly 300 may include a second semiconductor substrate 310 and a logic circuit layer 320. The logic circuit layer 320 may be integrated on the second semiconductor substrate 310. The logic circuit layer 320 may include transistors, conductive wiring and insulation layers configured to form the drive block 120, the readout block 130 and control block 140 of FIG. 1.

Although not shown in detail in the drawings, in the example, the logic circuit layer 320 and the circuit layer 230 may be directly bonded by a hybrid bonding process.

FIG. 3 is a cross-sectional view illustrating a unit pixel, which shows an enlarged view of the portion “A” of FIG. 2.

Referring to FIG. 3, the pixels PX may be defined by the pixel isolation layer 220 formed in the first substrate 210. In the example, the pixel isolation layer 220 may be disposed on two sides of the pixel PX. The photoelectric conversion elements PD may be formed in each of the pixels PX, respectively. In example embodiments, the pixel PX may be a small pixel having a width and length of about 0.1 μm to about 0.7 μm.

The anti-reflective layer 240 may be formed on the second surface 210b of the first substrate 210. The grid pattern 250 may be formed on the anti-reflective layer 240. The grid pattern 250 may be positioned at a location corresponding to the pixel isolation layer 220. In some cases, the grid pattern 250 may be formed as a hybrid type which further including a conductive layer disposed under the grid pattern 250. Further, a width of the grid pattern 250 may be equal to or greater than the width of the pixel isolation layer 220, but is not limited thereto. In example embodiments, the grid pattern 250 may have a first refractive index of about 1.

The color filter 260 may be formed over the grid pattern 250. The color filter 260 may transmit a specific color of a light for each pixel PX, as described above. The grid pattern 250 may prevent an optical crosstalk between the color filters 260 of the adjacent pixels PX. For example, each of the color filters 260 may be formed of or include at least one material including a second refractive index greater than the first refractive index. For example, the second refractive index may be about 1.6 to about 1.8.

The light concentration layer 270 have a thickness thinner than the thickness of conventional micro lens of the small pixel, as described above. The light concentration layer 270 may have a flat upper surface with substantially zero curvature. For example, the light concentration layer 270 may include at least one of a resist material, a thermosetting material or a transparent insulating material. In the examples, the light concentration layer 270 may be formed in a following manner. For example, a material for a light concentration layer may be coated on the color filter 260. Then, the material may be cured at a selected temperature. Thereafter, the light concentration layer 270 may be formed by etching back the cured material to a thickness operable as the light concentration layer 270. The thickness of the light concentration layer 270 may be changed by the width of the pixel PX and the wavelength of the incident light. For example, when the width of the pixel PX is approximately 0.56 μm, the thickness of the light concentration layer 270 may range from about 1/10 to about 1/20 of the wavelength of the incident light. For example, the light concentration layer 270 may be formed with a thickness of about 500 Å to about 1,000 Å. The light concentration layer 270 may have the second refractive index substantially the same as the refractive index of the color filter 260.

In some implementations, the light concentration layer 270 may be formed of or include an insulating material including a refractive index equal to or lower than the second refractive index. The light concentration layer 270 may be utilized as a passivation layer for the image sensing device.

The light concentration layer 270 may include the adjusting portion 275 formed in at least one of the regions corresponding to the edges of the pixel PX. The adjusting portion 275 may be configured in a shape of a trench. For example, when the light concentration layer 270 has a first surface in contact with the color filter 260 and a second surface opposite to the first surface, the adjusting portion 275 may have a shape of the trench etched from the second surface of the light concentration layer 270 toward the first surface of the light concentration layer 270. The adjusting portion 275 may be configured to change the thickness of the light concentration layer 270 so as to focus the incident light L onto the photoelectric conversion element PD.

For example, since the adjusting portion 275 may have the trench structure as described above, an interior of the adjusting portion 275 may be filled with air including the first refractive index. Therefore, when the incident light is incident on the adjusting portion 275 as shown in FIG. 3, the incident light passes the adjusting portion 275 including the first refractive index, the light concentration layer 270 including the second refractive index, the color filter 260 and the grid pattern 250 including the first refractive index. By implementing the adjusting portion 275 and the color filter 260 with different refractive indices, a stack structure of the adjusting portion 275 and the color filter 260 with different refractive indices may be configured to change the path of the incident light L, thereby changing the focal length, without the need for a separate micro lens.

In the example, a low-refractive-index material layer (for example, the adjusting portion: 275), a high-refractive-index material layer (for example, the light concentration layer 270), and another low-refractive-index material layer (for example, the grid pattern 250) are arranged, which provides the repetition of the low-refractive-index material layer.-As the incident light sequentially passes through a low-refractive-index material layer (for example, the adjusting portion: 275), a high-refractive-index material layer (for example, the light concentration layer 270), and another low-refractive-index material layer (for example, the grid pattern 250), the incident light may refract and the focal length of the incident light may be adjusted. Accordingly, by utilizing the refractive index differences between the material layers of the light incidence structure CS, the incident light may be concentrated onto the photoelectric conversion elements, similar to a micro lens.

In example embodiments, the adjusting portion 275 may be formed in the light concentration layer 270 and/or the color filter 260 corresponding to the high refractive index layer to precisely control the refraction path of the incident light. As a result, even small pixels may be reliably focused in the photoelectric conversion elements PD.

Although FIG. 3 illustrates a case where the bottom portion of the adjusting portion 275 is positioned within the light concentration layer 270, it may extend into the interior of the color filter 260, depending on the thickness of the light concentration layer 270 and the wavelength of the incident light.

As a result, even at small pixels PX, the focal length of incident light may be focused at the desired location without forming a highly curved micro lens.

In some implementations, the adjusting portion 275 may be formed in the color filter 260 only without being formed in the light concentration layer 270. In some implementations, the adjusting portion 275 of example embodiments may be configured in various forms.

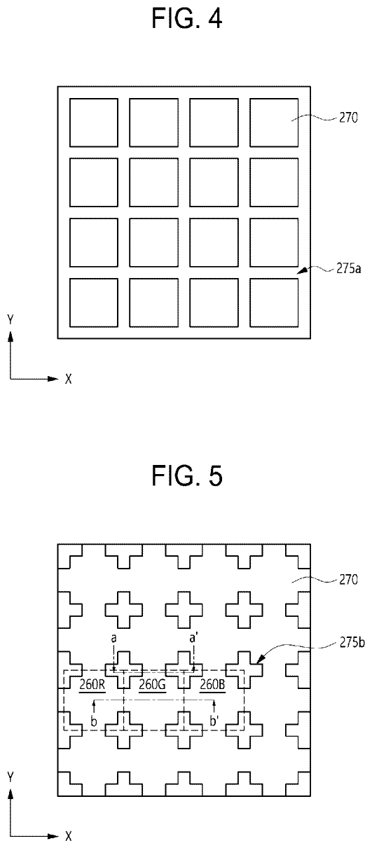

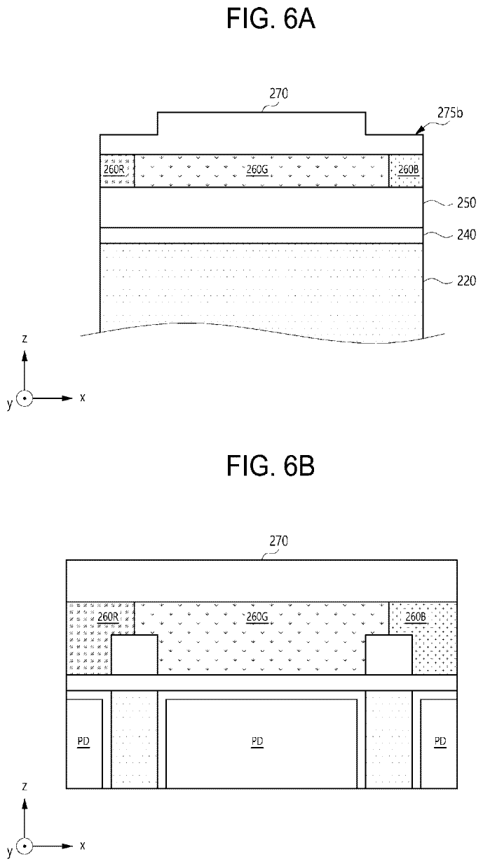

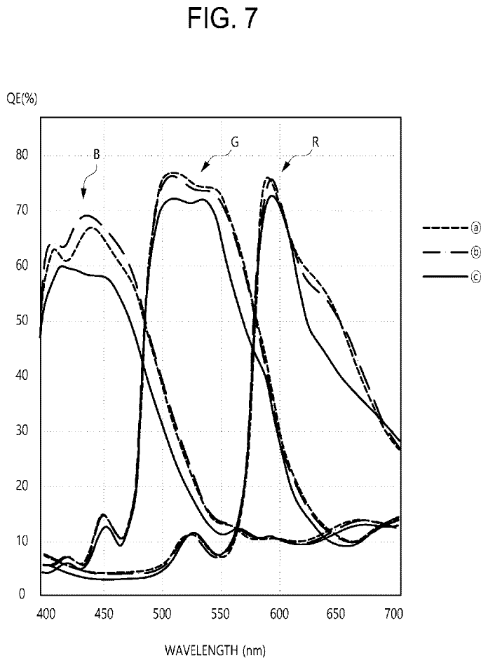

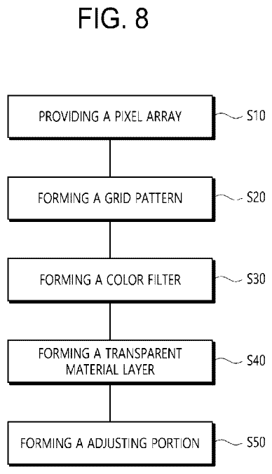

FIG. 4 is a perspective view illustrating a light concentration layer in accordance with example embodiments, and FIG. 5 is a perspective view illustrating a light concentration layer in accordance with example embodiments. FIG. 6A is a cross-sectional view taken along an A-A′ line in FIG. 5, and FIG. 6B is a cross-sectional view taken along a B-B′ line in FIG. 5.

Referring to FIGS. 3 and 4, an adjusting portion 275a may be formed in the light concentration layer 270 corresponding to the pixel isolation layer 220 and the grid pattern 250. In example embodiments, the adjusting portion 275a may be configured in the form of a mesh in which the adjusting portion 275a is provided as one unit along a row direction and a column direction by surrounding the light concentration layer 270 of each pixel. The adjusting portion 275a may be configured to define regions where the plurality of pixels PX will be formed.

In some implementations, as shown in FIGS. 3 and 5, an adjusting portion 275b may be formed in a form of a cross at a portion corresponding to a corner portion of each pixel PX. For example, referring to FIG. 5, the adjusting portion 275b may be disposed at corners of each pixel and have a cross-shape.

Referring to FIG. 6A, the adjusting portion 275b may be formed to overlap with a portion of the pixel isolation layer 220 extending in an x-axis. Although not shown, the adjusting portion 275b may be formed to overlap with a portion of the pixel isolation layer 220 extending in a y-axis of FIG. 5.

In some implementations, referring to FIG. 6B, the adjusting portion 275b may not be formed on the photoelectric conversion element PD except a corner of the pixel PX and the pixel isolation layer 220 on the outer side of the photoelectric conversion element PD, and only the light concentration layer 270 including the flat upper surface may be formed.

The adjusting portions 275a and 275b may be configured in various forms. The adjusting portions 275a and 275b may serve to adjust the focusing position of the incident light L per the pixel PX, and may also serve as marks for inspection of the pixels PX at the time of shipment of the image sensing device.

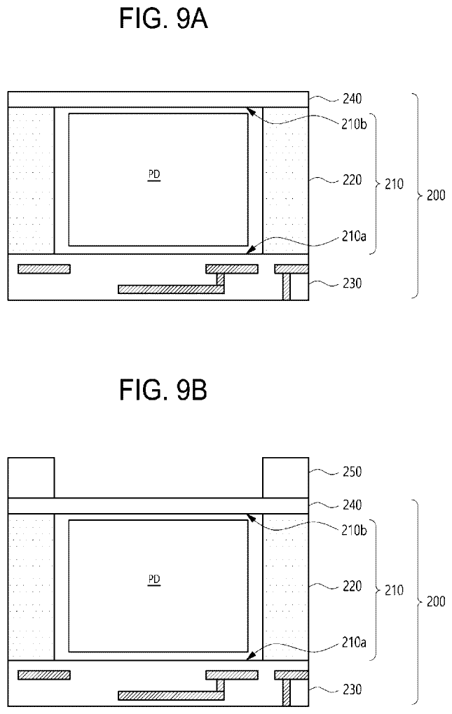

FIG. 7 is a graph showing quantum efficiency (QE) of an image sensing device in accordance with example embodiments.

In FIG. 7, a line \textcircled{a} may represent a QE distribution of the image sensing device including the light concentration layer 270 with the mesh-shaped adjusting portion 275a. A line \textcircled{b} may indicate a QE distribution of the image sensing device including the light concentration layer 270 including the cross-shaped adjusting portion 275b. A line \textcircled{c} may represent a QE distribution of a typical image sensing device in which a micro lens with a curvature may be formed for each pixel PX.

Referring to FIG. 7, the image sensing device including the small pixel PX of about 0.56 μm may generate a QE distribution of a blue color, a QE distribution of a green color and a QE distribution of a red color in a wavelength band of about 450 nm to about 495 nm, a wavelength band of about 495 nm to about 570 nm and a wavelength band of about 620 nm to about 780 nm, respectively.

Referring to FIG. 7, it can be noted that when the light concentration layer 270 including the mesh-shaped adjusting portion 275a and the cross-shaped adjusting portion 275b may be applied to the pixel array, a relatively higher QE distribution (\textcircled{a}, \textcircled{b}>\textcircled{c}) can be obtained as compared to the case when the micro lens are provided.

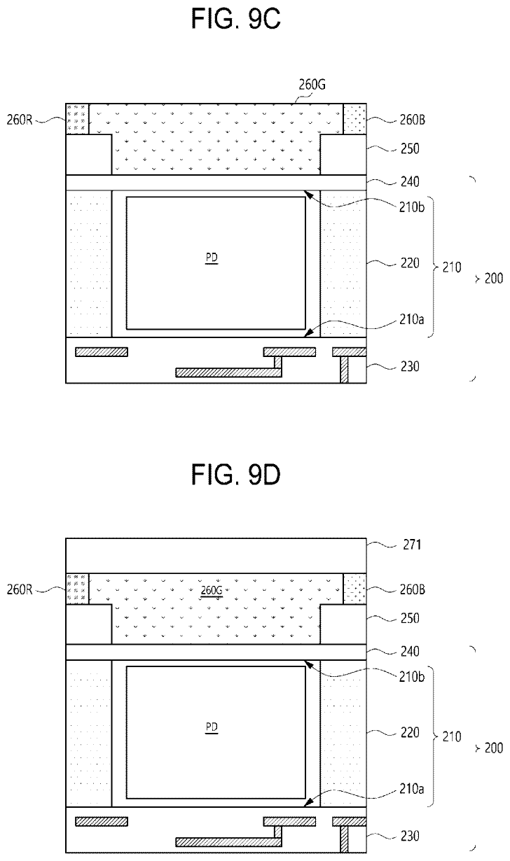

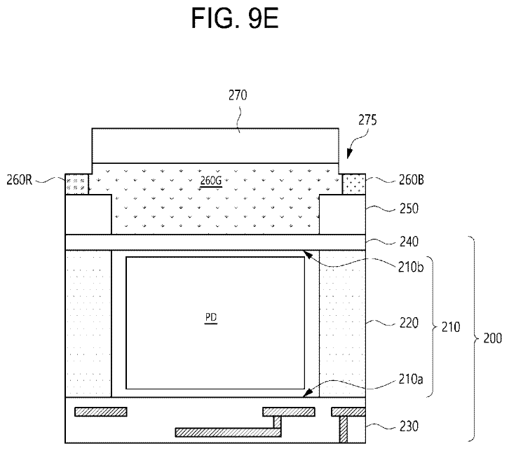

FIG. 8 is a flow chart illustrating a method of manufacturing an image sensing device in accordance with example embodiments. FIGS. 9A to 9E are cross-sectional views of each step illustrating a method of manufacturing an image sensing device in accordance with example embodiments.

Referring to FIGS. 8 and 9A, a pixel array 200 may be provided (S10). In the example, the pixel array 200 may include a first substrate 210, a pixel isolation layer 220, a photoelectric conversion element PD and an anti-reflective layer 240, as described above.

The first substrate 210 may include a first conductive type impurity, for example, a P-type impurity. The pixel isolation layer 220 may be formed using various techniques known in the art to confine the plurality of pixels PX in the first substrate 210. For example, a planar structure of the pixel isolation layer 220 may have a mesh-like shape, and a cross-sectional structure of the pixel isolation layer 220 may have a through or segmented shape. Further, the pixel isolation layer 220 may be embedded with an insulating material, a metallic material, or a conductive impurity material to optically separate neighboring pixels PX.

Each of the photoelectric conversion elements PD may be formed in the first substrate 210 limited to the pixel PX. In example embodiments, a second conductive type impurity, for example, an n-type impurity, may be implanted in a form of a well into the first surface 210a of the first substrate 210 corresponding to the pixel PX to form a first impurity region (not shown). A p-type impurity including a high concentration in a target region of the first impurity region may be implanted in a form of a junction region to form a second impurity region (not shown). Accordingly, the photoelectric conversion element PD in the form of a p-n diode may be formed.

Next, a circuit layer 230 may be formed on the first surface 210a of the first substrate 210 to form the photoelectric conversion structure PDS (see FIG. 2). The circuit layer 230 may include a plurality of transistors electrically connected with the photoelectric conversion element PD on the first surface 210a of the first substrate 210, a plurality of conductive wirings electrically connected between the plurality of transistors, and an insulating interlayer. A process for forming the plurality of transistors, the plurality of multilayer conductive wiring and the insulating interlayer may be the same as a conventional process.

Thereafter, the first substrate 210 on which the circuit layer 230 may be formed may be flipped so that the second surface 210b faces upward. Next, the anti-reflective layer 240 may be formed on the second surface 210b of the first substrate 210 by various deposition methods. The anti-reflective layer 240 may include at least one of the following materials: silicon oxide, silicon nitride, silicon oxynitride, aluminum oxide, hafnium oxide, and combinations thereof, as described above.

Next, referring to FIGS. 8 and 9B, the grid pattern 250 may be formed on the anti-reflective layer 240 (S20). The grid pattern 250 may be formed at locations corresponding to the pixel isolation layer 220, respectively, to define color filter regions corresponding to pixels PX.

In example embodiments, the grid pattern 250 may be formed in the following manner. First, a sacrificial pattern (not shown) may be formed on the anti-reflective layer 240. A capping layer (not shown) may be formed to enclose the sacrificial pattern. The sacrificial pattern surrounded by the capping layer may be selectively removed. Accordingly, a space in the capping layer may be utilized as the grid pattern 250. However, the above-described method may be only an example, and hybrid grid patterns including a laminated structure of a conductive layer and an air layer, as well as the grid patterns in various other ways, may be applied herein.

Then, referring to FIGS. 8 and 9C, color filters 260R, 260G and 260B may be formed in the color filter regions defined by the grid pattern 250, respectively (S30). For reference, FIG. 9C illustrates an example where filters including different colors may be disposed in the color filter regions on both sides relative to the grid pattern 250, identical color filters may be disposed.

Further, when the color filter may include the red filter 260R, the green filter 260G and the blue filter 260B, the color filter may be formed in the following manner.

First, a green colored filter material layer may be coated on the anti-reflective layer 240. The green color filter material layer may include a photoresist material containing a green pigment. Subsequently, the green color filter material layer may be patterned to be located in a set color filter region (hereinafter, the first color filter region), such that the green filter 260G may be formed in the first color filter region.

Next, a red colored filter material layer may be coated on the anti-reflective layer 240 and the green filter 260G. The red color filter material layer may include a photoresist material containing a red pigment. Thereafter, the red color filter material layer may be patterned to be located in a set color filter region (hereinafter referred to as a second color filter region), such that the red filter 260R may be formed in the second color filter region.

Next, a blue color filter material layer may be coated on the anti-reflective layer 240, the green filter 260G and the red filter 260R. Thereafter, the blue color filter material layer may be patterned to be located in a set color filter region (hereinafter, the third color filter region), such that the blue filter 260B may be formed in the third color filter region.

A descum process may be performed prior to the step of applying the green color filter material layer, red color filter material layer, and blue color filter material layer.

Next, referring to FIGS. 8 and 9D, a transparent material layer 271 may be formed on the color filter 260 (S40). The transparent material layer 271 may have a flat top surface. Further, the transparent material layer 271 may have a refractive index greater than the grid pattern 250, and may have a refractive index equal to or less than the color filters 260R, 260G and 260B. Further, the transparent material layer 271 may have a hardness that allows an etching process to proceed.

For example, the transparent material layer 271 may be a light-transmissive resist material. The light-transmissive resist material may be formed, for example, by a spin coating. Subsequently, the light-transmissive resist material may be cured at a predetermined temperature to form the transparent material layer 271 including the flat surface with certain hardness. When the transparent material layer 271 may have the light-transmissive resist material, the transparent material layer 271 may have substantially the same refractive index as the color filters 260R, 260G and 260B.

Alternatively, the transparent material layer 271 may include an insulating layer or a thermosetting resin material including a refractive index greater than the grid pattern 250 and including the same or lesser the refractive index than the color filters 260R, 260G and 260B. When the transparent material layer 271 may be formed of the insulating layer or a resinous material, the light concentration layer 270 including the transparent material layer 271 may be used as a passivation layer for the pixels PX and the color filters 260R, 260G and 260B.

Such the transparent material layer 271 may be formed with a thickness of about 1/10 to about 1/20 of the wavelength of the incident light, for example, about 500 Å to about 1,000 Å, but is not limited thereto. The thickness of the transparent material layer 271 may be variable depending on the size of the pixel and the wavelength of the incident light.

Next, referring to FIGS. 8 and 9E, the adjusting portion 275 may be formed on a selected portion of the transparent material layer 271 (S50). The selected portion may be a portion corresponding to the entirety of the pixel isolation layer 220, as shown in FIG. 4. Alternatively, the selected portion may be a portion corresponding to a corner portion of the pixel isolation layer 220, as shown in FIG. 5.

For example, the adjusting portion 275 may be formed by etching the selected portion of the transparent material layer 271 and/or the color filters 260R, 260G and 260B below it corresponding to the selected portion.

For example, the adjusting portion 275 may be the same as or different from the width of the grid pattern 250. In example embodiments, the transparent material layer 271 and/or the color filters 260R, 260G and 260B may be etched such that the adjusting portion 275 may have a depth of about 500 Å to about 1,000 Å and a width of about 1,500Å to about 2,000 Å, thereby forming a light concentration layer 270 with the adjusting portion 275.

In example embodiments, the adjusting portion 275 of FIG. 3 may illustrate an example where the bottom of the adjusting portion 275 may be located in the light concentration layer 270, and FIG. 9E may illustrate an example where the bottom of the adjusting portion 275 may be located in the color filters 260R, 260G and 260B.

Since the adjusting portion 275 may be a kind of spatial part, such as a trench, there may be air with a refractive index of about 1 in the adjusting portion 275. Therefore, at a boundary part of the pixel PX (i.e., at a top of the pixel isolation layer), when viewed in the direction of the incident light L (e.g., in the-z direction), the adjusting portion 275 filled with air including a relatively low refractive index, the light concentration layer 270 and the color filter 260 including a higher refractive index than the air, and the grid pattern 250 including a relatively low refractive index may be arranged in this order.

Then, when the incident light L may be transmitted from the adjusting portion 275, which may have a relatively low refractive index, to the light concentration layer 270 and/or the color filter 260, which may have a relatively high refractive index, the incident light L may be refracted toward the photoelectric conversion element PD on the inner side of the pixel PX. Thus, the photoelectric conversion element PD of the small pixel may be focused without providing a micro lens with a large curvature, thereby improving the image quality of the image sensing device.

According to this embodiment of the disclosed technology, the focusing position of the incident light of a small pixel may be adjusted by changing the path of the incident light by stacking layers including different refractive indices. Since the layers with different refractive indices may perform the role of a lens by themselves, there may be no need to provide a separate high-curvature micro lens, and the incident light may be focused to the desired position, thereby improving the QE characteristics of the image sensing device.

The image sensing device of example embodiments may utilize the flat light concentration layer, which may reduce damage to the micro lens during shipment and protect the image sensing device from external factors as the light concentration layer may also act as the passivation layer.

In addition, even if the flat light concentration layer may be formed on the image sensing device, the trench-shaped adjusting portion may be formed to guide the position of the pixels, thus preventing errors during factory inspection of the image sensing device.

While a number of illustrative embodiments of the disclosed technology have been described with reference to preferred embodiments, it should be understood that other modifications and embodiments can be devised by those skilled in the art.

What is claimed is:

1. An image sensing device comprising:
a photoelectric conversion structure including a pixel isolation layer configured to define a plurality of pixels, each pixel including a photoelectric conversion element configured to generate electronic signals in response to a reception of light incident on the each pixel; and
a light incident structure disposed on the photoelectric conversion structure and configured to focus an incident light onto the photoelectric conversion element,
wherein the light incident structure comprises:
a grid pattern including a first refractive index and configured to overlap the pixel isolation layer;
a plurality of color filters positioned on the grid pattern and including a second refractive index greater than the first refractive index; and
a light concentration layer positioned on the plurality of color filters and including a flat upper surface to the incident light, and
wherein the light concentration layer comprises an adjusting portion disposed on at least a portion of the light concentration layer and disposed to overlap with the pixel isolation layer and configured to adjust a focusing position of the incident light.

2. The image sensing device of claim 1, wherein the grid pattern includes air.

3. The image sensing device of claim 1, wherein the light concentration layer has a refractive index substantially same as the second refractive index.

4. The image sensing device of claim 1, wherein the adjusting portion has a trench structure having a depth that is less than a thickness of the light concentration layer.

5. The image sensing device of claim 1, wherein the adjusting portion is formed to overlap the pixel isolation layer.

6. The image sensing device of claim 1, wherein the adjusting portion has a cross shape at a corner portion of the each pixel.

7. The image sensing device of claim 1, wherein the adjusting portion includes air.

8. The image sensing device of claim 1, wherein a bottom surface of the adjusting portion is located lower than the flat upper surface of the light concentration layer, and the bottom surface of the adjusting portion is positioned in the light concentration layer.

9. The image sensing device of claim 1, wherein a bottom surface of the adjusting portion is located lower than the flat surface of the light concentration layer, and the bottom surface of the adjusting portion is positioned in the plurality of color filters.

10. The image sensing device of claim 1, wherein the light concentration layer comprises a material including a third refractive index greater than the first refractive index and equal to or less than the second refractive index.

11. The image sensing device of claim 10, wherein the light concentration layer comprises at least one of a resist layer, a thermosetting resin, or an insulation layer.

12. The image sensing device of claim 1, wherein a thickness of the light concentration layer ranges from 1/10 to 1/20 of a wavelength of the incident light.

13. An image sensing device comprising:
a first substrate including a front side and a back side opposite to the front side;
a plurality of photoelectric conversion elements formed in the first substrate;
a pixel isolation layer formed in the first substrate and configured to optically separate the plurality of photoelectric conversion elements from each other;
an anti-reflective layer formed over the back side of the first substrate;
a grid pattern including a first refractive index and formed over the anti-reflective layer to overlap the pixel isolation layer;
a plurality of color filters formed over the grid pattern and including a second refractive index higher than the first refractive index; and
a passivation layer configured to cover the plurality of color filters, the passivation layer including a flat upper surface and having a first thickness,
wherein the passivation layer comprises an adjusting portion disposed at least one portion of the passivation layer that corresponds to the pixel isolation layer, the adjusting portion having a second thickness smaller than the first thickness.

14. The image sensing device of claim 13, wherein the passivation layer comprises a transparent material including a refractive index greater than the first refractive index and equal to or less than the second refractive index, and
wherein air including the first refractive index is positioned outside the passivation layer and inside the adjusting portion.

15. The image sensing device of claim 13, wherein the adjusting portion is formed to overlap the pixel isolation layer.

16. The image sensing device of claim 13, wherein the adjusting portion is formed at a portion corresponding to a corner portion of the pixel isolation layer, and the adjusting portion has a cross shape in a plan view.

17. The image sensing device of claim 13, wherein a bottom surface of the adjusting portion is located in the passivation layer.

18. The image sensing device of claim 13, wherein a bottom surface of the adjusting portion is located in the plurality of color filter.

19. The image sensing device of claim 13, wherein the passivation layer comprises at least one of a resist layer, a thermosetting resin, or an insulation layer.

20. The image sensing device of claim 13, wherein the passivation layer has a thickness of from 1/10 to 1/20 of a wavelength of an incident light.

21. The image sensing device of claim 13, further comprising a circuit layer formed on the front side of the first substrate and including pixel transistors in connection with at least one of the plurality of photoelectric conversion elements to generate a pixel signal.

22. The image sensing device of claim 21, further comprising a logic assembly electrically coupled to the circuit layer and disposed under the circuit layer.
